(19) United States
(12) Patent Application Publication
(10) Pub. No.: US 2024/0038650 A1
(43) Pub. Date: Feb. 1, 2024

(54) METHOD OF MANUFACTURING SEMICONDUCTOR DEVICES AND CORRESPONDING SEMICONDUCTOR DEVICE

(71) Applicant: STMicroelectronics S.r.l., Agrate Brianza (MB) (IT)

(72) Inventors: Damian HALICKI, Agrate Brianza (IT); Michele DERAI, Milano (IT)

(73) Assignee: STMicroelectronics S.r.l., Agrate Brianza (MB) (IT)

(21) Appl. No.: 18/223,838

(22) Filed: Jul. 19, 2023

(30) Foreign Application Priority Data
Jul. 28, 2022 (IT) 102022000016011

(51) Int. Cl. H01L 23/498; H01L 23/31; H01L 25/065; H01L 21/56

(52) U.S. Cl. CPC H01L 23/49838; H01L 23/3107; H01L 28/10; H01L 25/0655; H01L 21/561; H01L 23/49822

(57) ABSTRACT

Semiconductor devices of the type currently referred to as a System in a Package (SiP) and having embedded therein a transformer are produced by embedding at least one semiconductor chip in an insulating encapsulation at a first portion thereof. Over a second portion thereof at least partly non-overlapping with the first portion, a stacked structure is formed including multiple layers of electrically insulating material as well as respective patterns of electrically conductive material. The respective patterns of electrically conductive material have: a planar coil geometry for providing electrically conductive coils such as the windings of a transformer and a geometrical distribution providing electrically conductive connections to one or more semiconductor chips.

### PRIORITY CLAIM

This application claims the priority benefit of Italian Application for Patent No. 102022000016011, filed on Jul. 28, 2022, the content of which is hereby incorporated by reference in its entirety to the maximum extent allowable by law.

### TECHNICAL FIELD

The description relates to manufacturing semiconductor devices comprising electrical coils, for instance in a transformer.

Solutions as described herein can be applied, for instance, to DC/DC converters, galvanic insulators and, generally, to semiconductor device packages having coils embedded therein.

### BACKGROUND

Semiconductor devices of the type currently referred to as a System in a Package (SiP) may have embedded therein (high performance) transformers.

These transformers can be formed starting from a core laminate. This approach may be fairly expensive; additionally, the presence of leadframe portions onto which the transformer rests can lead to coupling with the metal (e.g., copper) of the leadframe with associated losses. These losses are primarily due to the metallic frame acting as a shield thus adversely affecting mutual coupling of the coils.

A transformer integrated with a so-called Fan Out Panel Level Package (FOPLP) formed over silicon is described, for instance, in Z. Wang, et al: “A transformer using two RDL metal layers based on Fan-Out Panel Level Package Technology”, 2021 J Phys: Conf. Ser. 1971 012041 (incorporated by reference). Such an approach also causes coupling with silicon and ensuing losses. It is noted that the transformer has a size comparable with the size of the die, which makes it unsuitable for power applications.

There is accordingly a need in the art to adequately address the issues discussed in the foregoing.

### SUMMARY

One of more embodiments relate to a method.

One of more embodiments may also relate to a corresponding semiconductor device having a coil (e.g., a transformer) embedded therein.

One or more embodiments provide a circuit layout wherein a coil is integrated in a System in a Package (SiP) using Panel Embedded Package (PEP) technology.

In various embodiments, coils can be formed in metallization levels of PEP technology giving rise to a System in Package layout wherein the die/dice and the coil/coils are (at least substantially) not overlapping with each other.

Advantages of solutions as described herein can be summarized as follows: one or more coils, e.g., for a transformer can be created using a metal (e.g., copper) plating thus avoiding mounting a coil in a package; electrical performance is improved with inductance increased thanks to the absence of a metal pad for the coil or coils; resistance is also reduced due to wires being replaced via, e.g., DCI interconnections with advantages also in terms of coupling coefficient and Q-factor; the overall package thickness can be reduced with possible reduction of package footprint; and flexibility in package layout is increased with a possible cost reduction.

Solutions as described herein take advantage of LDS/DCI technology and contemplate forming the coil/transformer directly in the package molding.

In that way, providing a support frame, a transformer substrate and related processes (wire bonding/die/substrate attach) can be avoided.

Solutions as described herein may also facilitate reducing package dimensions (both in terms of footprint and of thickness) while improving electrical performance.

### BRIEF DESCRIPTION OF THE DRAWINGS

One or more embodiments will now be described, by way of example only, with reference to the enclosed figures, wherein:

FIG. 1 is a perspective view of a conventional system in a package (SiP) having a transformer embedded therein;

FIG. 2 is a lateral view of a conventional system in a package (SiP) taken along line II-II of FIG. 1;

FIG. 3 is a perspective view of a system in a package (SiP) according to embodiments of the present description;

FIG. 4 is a plan view of the system in a package (SiP) of FIG. 3;

FIG. 5 is a lateral view of a system in a package (SiP) according to embodiments of the present description taken along line V-V of FIG. 4;

FIG. 6 is a perspective view of another system in a package (SiP) according to embodiments of the present description;

FIG. 7 is a plan view of the system in a package (SiP) of FIG. 6;

FIG. 8 is a lateral view of a system in a package (SiP) according to embodiments of the present description taken along line VIII-VIII of FIG. 7; and

FIGS. 9A to 9L are illustrative of a sequence of steps according to embodiments of the present description.

### DETAILED DESCRIPTION

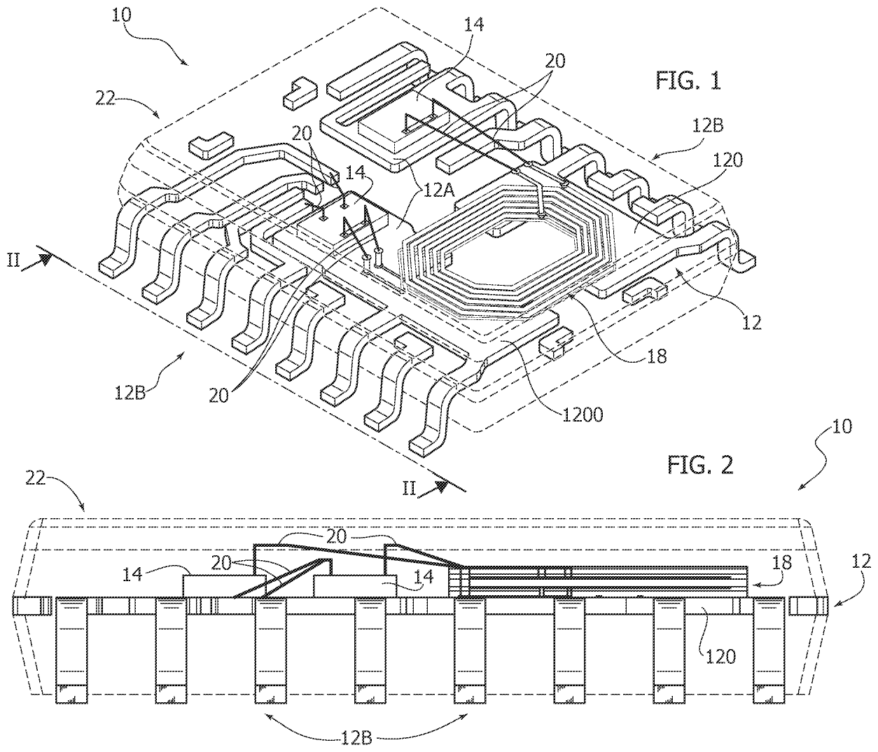

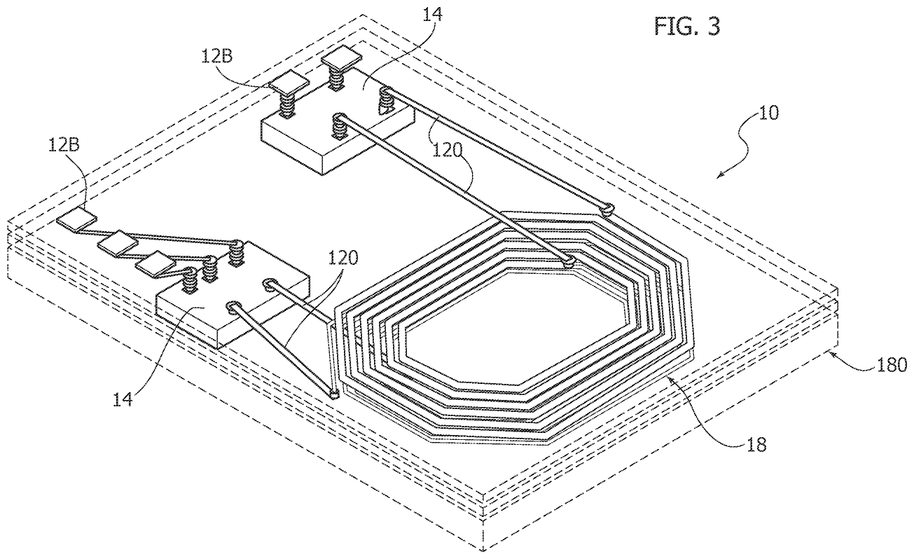

It is noted that in FIGS. 1 to 8, various elements are represented as “transparent” in order not to obscure the presence of other elements in the figures. This applies, e.g., to the lateral views of FIGS. 2, 5 and 8.

The figures are drawn to clearly illustrate the relevant aspects of the embodiments and are not necessarily drawn to scale.

Corresponding numerals and symbols in the different figures generally refer to corresponding parts unless otherwise indicated: consequently, like parts or elements are indicated in the various figures with like reference signs, and a corresponding description will not be repeated for each and every figure. The edges of features drawn in the figures do not necessarily indicate the termination of the extent of the feature.

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

For simplicity and ease of explanation, throughout this description manufacturing a single device will be described, being otherwise understood that current manufacturing processes of semiconductor devices involve manufacturing concurrently plural devices that are separated into single individual devices in a final singulation.

FIGS. 1 and 2 are exemplary of a conventional System in a Package (SiP) 10 comprising a substrate (leadframe) 12 including die-mounting areas (die pads) 12A plus an array of electrically conductive leads 12B distributed sideways of the die pads 12A. One or more semiconductor dice or chips 14 are mounted at the die pads 12A.

The designation “leadframe” (or “lead frame”) is currently used (see, for instance the USPC Consolidated Glossary of the United States Patent and Trademark Office) to indicate a metal frame that provides support for an integrated circuit chip or die as well as electrical leads to interconnect the integrated circuit in the chip or die to other electrical components or contacts.

Essentially, a leadframe comprises an array of electrically-conductive formations (or leads, e.g., 12B) that from an outline location extending inwardly in the direction of a semiconductor chip or die (e.g., 14) thus forming an array of electrically-conductive formations from die pads (e.g., 12A) configured to have—at least one—semiconductor integrated circuit chip or die attached thereon.

The package 10 also includes, resting on support portions 1200 formed in the leadframe 12, a transformer 18.

The transformer 18 may comprise primary and secondary windings (coils) connected to the dice or chips 14 via wiring 20.

An encapsulation 22 of insulating material (an epoxy resin, for instance) is molded onto the assembly thus formed leaving the leads 12B protruding from the encapsulation 22 (which is shown in transparency in order not to obscure the other elements of the package 10).

The encapsulation 22 surrounds the circuit material to protect it from corrosion or physical damage while facilitating mounting of the electrical contacts, connecting the package to a mounting substrate (a Printed Circuit Board (PCB) for instance—not visible in the figures).

During operation, the coils in the transformer 18 create a magnetic field that inevitably interacts with the metal (e.g., copper) material of the leadframe 12 (at the portions designated 1200) which undesirably affects electrical performance.

The wiring patterns 20 may also create constraints in terms of electrical performance and package footprint dimensions. It is observed that standard wire interconnections result in (very) poor layout flexibility in the case of packages having embedded coils such as the transformer 18.

Embedding such coils in a standard leadframe-based package also results in a fairly complex assembly process. Conventional solutions to implement a transformer in a package may in fact involve integrating a transformer built over a dielectric substrate (e.g., of the type using ball grid array/land grid array (BGA/LGA) arrangements) connected through conventional wire bonding to silicon dice. A leadframe having a customized design may be required in order to facilitate complying with galvanic isolation constraints and reducing the presence of metal parts.

To summarize: the substrate of the transformer (this may be a 6-layer substrate having a thickness of, e.g., 0.4 mm) rests on one or more metal pads 1200 in the leadframe, which leads to a reduction of electrical performance; standard interconnections using wires such as 20 also adversely affect electrical performance insofar as they may introduce undesired electrical resistance; a coil, such as a transformer coil 18 housed on a substrate as exemplified in FIGS. 1 and 2, may have a high cost; a “specialized” leadframe 12 may be required to accommodate the coil or coils; the substrate housing the coil takes a certain space in the package 10, resulting in a footprint increase; and additional and fairly complex assembly steps may be involved.

Laser direct structuring (LDS) is a laser-based machining technique now widely used in various sectors of the industrial and consumer electronics markets, for instance for high-performance antenna integration, where an antenna design can be directly formed onto a molded plastic part. In an exemplary process, the molded parts can be produced with commercially available insulating resins that include additives suitable for the LDS process; a broad range of resins such as polymer resins like PC, PC/ABS, ABS, LCP are currently available for that purpose. A laser beam can be used to transfer (“structure”) a desired electrically conductive pattern onto a plastic molding that may then be subjected to metallization to finalize a desired conductive pattern. Metallization may involve electroless plating followed by electrolytic plating. Electroless plating, also known as chemical plating, is a class of industrial chemical processes that creates metal coatings on various materials by autocatalytic chemical reduction of metal cations in a liquid bath. In electrolytic plating, an electric field between an anode and a workpiece, acting as a cathode, forces positively charged metal ions to move to the cathode where they give up their charge and deposit themselves as metal on the surface of the workpiece.

LDS is oftentimes referred to also as direct copper interconnection (DCI). This is primarily with reference to a package family wherein conventional wire bonding is replaced with copper plated vias and lines (traces). Laser Induced Strip Interconnection (LIST) and Panel Embedded Package (PEP) are designations of possible sub-families of DCI packages.

United States Patent Publication Nos. 2018/0342453 A1, 2019/0115287 A1, 2020/0203264 A1, 2020/0321274 A1, 2021/0050226 A1, 2021/0050299 A1, 2021/0183748 A1, or 2021/0305203 A1 (all of which are incorporated herein by reference) are exemplary of the possibility of applying LDS technology in manufacturing semiconductor devices.

Solutions as described herein may take advantage of LDS/DCI technology as a solution to provide device interconnections with a substrate via metal (such as copper) grown (directly) with additive processes.

A Ti/Cu sputtering process can be used to create a seed layer for both coils and interconnections. This may be followed by metallization (growing metal such as copper via a plating process, for instance) to grow a thicker conductive structure.

Providing coils embedded in a package is thus simplified with overall electrical performance improved.

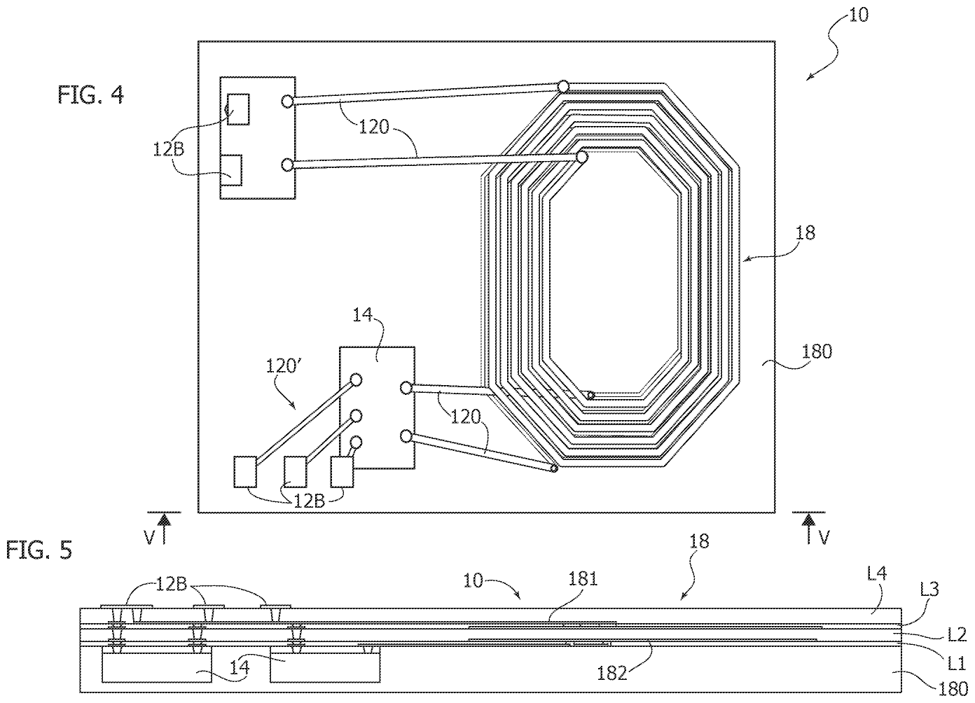

Two possible implementations of solutions as described herein are illustrated in FIGS. 3 to 5 and FIGS. 6 to 8, respectively.

For the sake of simplicity and in order to facilitate appreciating the advantages of the solutions described herein, in FIGS. 3 to 8 parts or elements like parts or elements already discussed in connection with FIGS. 1 and 2 are indicated (at least in part) with like reference symbols.

It will be otherwise appreciated the fact that certain parts or elements are indicated with like reference symbols in FIGS. 1 and 2 and in FIGS. 3 to 8 does not necessarily mean that these parts or elements are implemented in the same manner.

Generally, (also) in FIGS. 3 to 8, numerals 14 denote semiconductor chips coupled to the coils (primary side and secondary side) of a transformer 18, while the electrically conducting pins or leads providing electrical contacts for the package 10 are indicated as 12B.

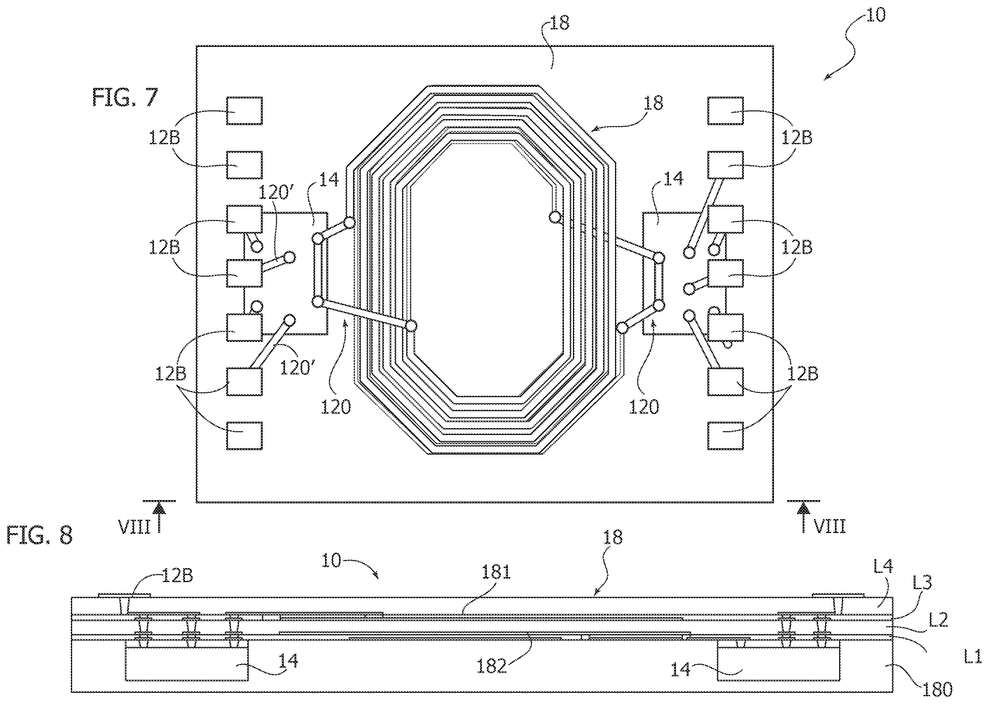

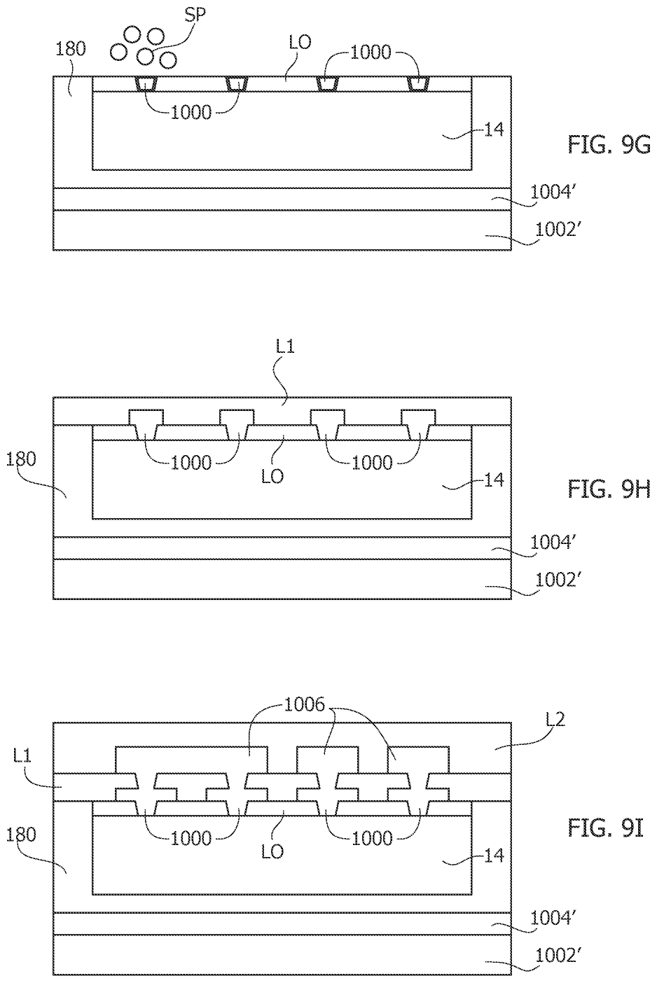

As better appreciable in the lateral views of FIGS. 5 and 8, in solutions as described herein, both the coils 181, 182 (at the primary and the secondary sides of the transformer 18) can be formed with PEP technology.

This gives rise to a sandwiched structure comprising (from the bottom to the top in FIG. 5): a substrate 180 (e.g., an insulating layer of mold material 180 such as epoxy resin such as the encapsulation 22 of FIGS. 1 and 2) having a thickness of, e.g., 450 microns having the integrated circuit chips or dice 14 embedded therein (in a manner known per se to those of skill in the art); and a stacked arrangement of (e.g., four) layers L1, L2, L3, L4 of electrically insulating material having the primary and secondary coils 181, 182 of the transformer 18 and the associated wiring (designated 120) formed therein as respective patterns of electrically conductive material.

Figures such as FIG. 5 are thus exemplary of embedding at least one semiconductor chip 14 in an insulating encapsulation 180 at a first portion thereof, and forming over a second portion of the insulating encapsulation 180 at least partly non-overlapping with the first portion of the insulating encapsulation 180 one or more electrically conductive coils 181, 182. These coils have a planar coil geometry and a geometrical distribution of electrically conductive connections 120 to the semiconductor chip 14.

Figures such as FIG. 5 are likewise exemplary of forming over the insulating encapsulation 180 having the semiconductor chip 14 embedded in the first portion stacked structure of layers. The layers in the stacked structure include electrically insulating material L1, L2, L3, L4 as well as respective patterns 1006, 1008, 12B of electrically conductive material.

These patterns of electrically conductive material have: either a planar coil geometry providing electrically conductive coils 181, 182; or a geometrical distribution, thus providing electrically conductive connections 120.

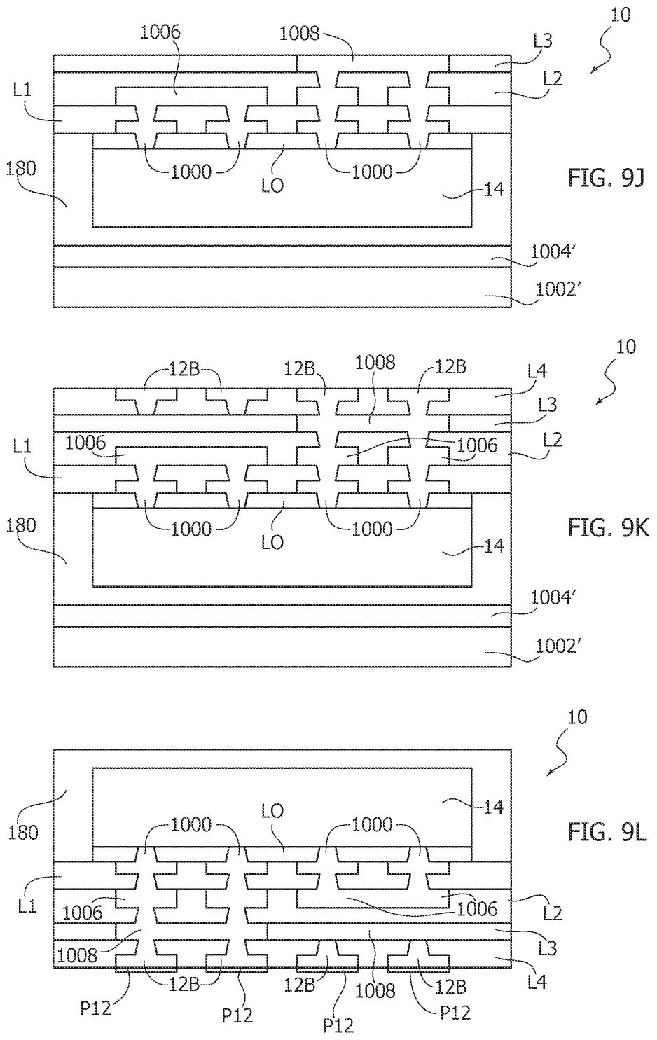

As further discussed in the following, these layers L1 to L4 can be laminated at a “panel” level over an underlying layer (referred to as L0 in FIGS. 9A to 9L) that can be laminated at “wafer” level.

Advantageously, these layers can comprise sheets/films of an LDS/DCI molding compound suited for processing as discussed in the following The laminated film can be an Ajinomoto Build-up Film® (ABF), an organic thermosetting film commercialized by the Ajinomoto Group.

Merely by way of example, the layers in question may have the following thicknesses: L1: 50 microns, L2: 100 microns, L3: 50 microns, and L4: 150 microns.

Of course, the quantitative values reported in the foregoing are merely exemplary and not limiting for the embodiments.

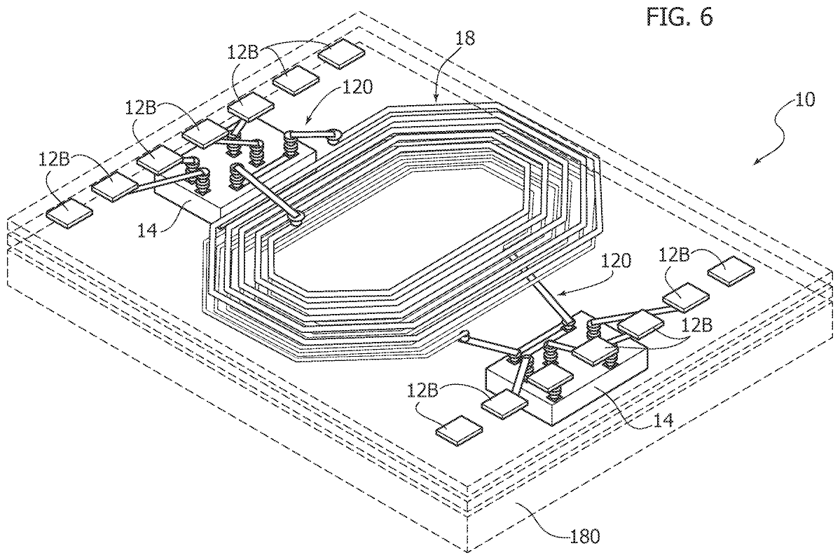

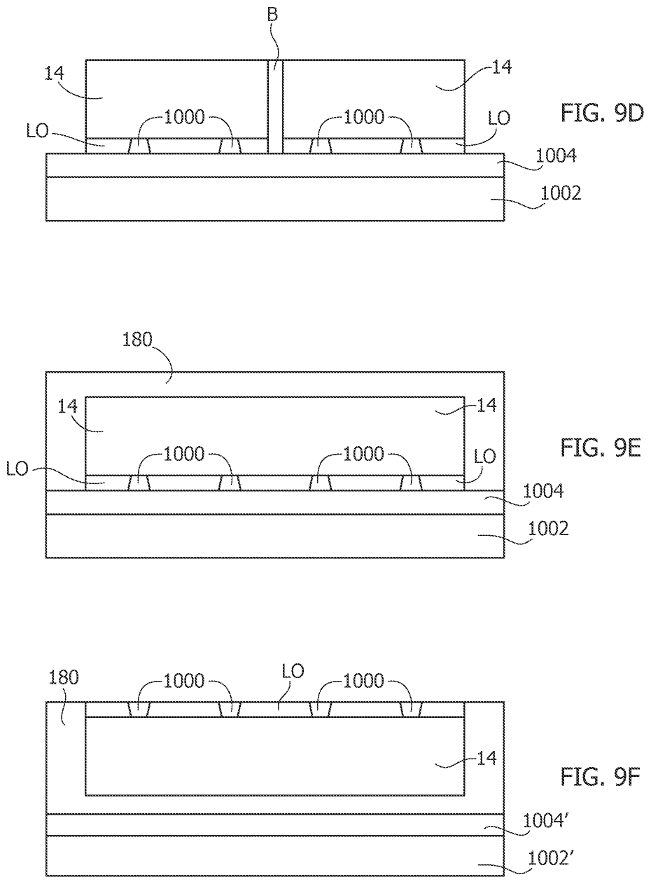

As further detailed in the description of the sequence of steps of FIGS. 9A to 9L, processing of the substrate 180 and the layers L0, L1, L2, L3, L4 involves forming therein electrically conductive patterns such as vias and electrically conductive lines to provide: the coils (primary and secondary windings 181, 182) of the transformer 18; and the wiring 120 as well as through vias that facilitate (see primarily FIGS. 4 and 7) electrical connection of the dice or chips 14 with the coils or windings of the transformer 18, and—possibly—(see reference 120′ in FIGS. 4 and 7) electrically conductive lines between the chips or dice 14 and associated leads 12B.

In solutions as described herein one or more semiconductor chips 14 are thus arranged at a first portion of a substrate 180 and one or more electrically conductive coils 181, 182 are formed over a second portion of the substrate 180. The second portion is at least partly non-overlapping with the first portion.

The coil or coils 181, 182 have: a planar coil geometry; and a geometrical distribution of electrically conductive connections 120 to the semiconductor chip or chips 14.

Solutions as described herein comprise forming over the second portion of the substrate 180 a stacked structure of layers of electrically insulating material L0, L1, L2, L3, L4 where respective patterns (see, e.g., 1000, 1006, 1008, 12B in FIGS. 9A to 9L) of electrically conductive material are formed as further detailed in connection with FIGS. 9A to 9L.

These respective patterns of electrically conductive material have: the planar coil geometry of the coil or coils 181, 182, thus providing such coil or coils (transformer windings); or the geometrical distribution of the electrically conductive connections 120 to the semiconductor chip or chips 14, thus providing such.

As appreciable in FIGS. 3 to 8, the chips 14 are advantageously non-overlapping with the coils of the transformer 18.

The (at least substantial) absence of overlapping between the chips 14 and the coils of the transformer 18 was found to be advantageous as this minimizes undesired mutual influence between the two.

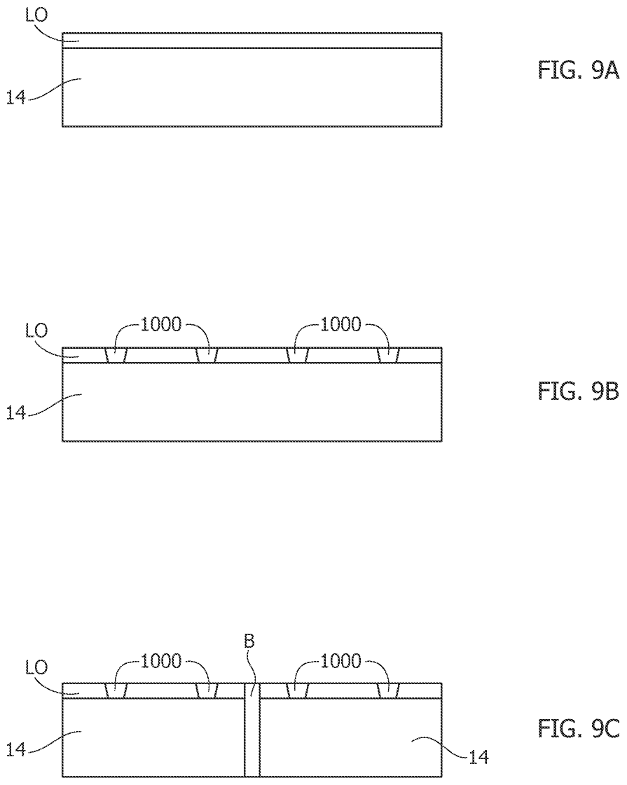

The comparison of FIGS. 3 to 5 (on the one side) and FIGS. 6 to 8 (on the other side) highlights the possibility of optimizing the layout (and thus the length) of the electrically conductive lines 120 that couple the dice 14 to the transformer 18.

FIGS. 3 to 5 are essentially exemplary of how the SiP of FIG. 1 may “look like” if implemented using PEP technology. The design of the transformer 181, 182 is essentially unchanged; the dice 14 are identical and placed at the same distance from the transformer: performance is improved due to most of the wiring and the leadframe being dispensed with.

FIGS. 6 to 8 are exemplary of a (possible) optimization of the solution of FIGS. 3 to 5, showing how the flexibility provided by PEP technology can further improve performance.

Shorter die-to-transformer connection as illustrated in FIGS. 6 to 8 facilitates reducing the overall size of the package 10.

For instance (and by way of non-limiting example) a system layout as exemplified in FIG. 4 can be implemented on a 6 mm×8 mm substrate of rectangular size while a system layout as exemplified in FIG. 7 can be implemented on a substrate 180 of 5.5×7 mm of rectangular size.

Once more, those values are merely exemplary and not limiting of the embodiments.

Embodiments as exemplified in FIGS. 3 to 8 were found to provide significant advantages over conventional layouts as exemplified in FIGS. 1 and 2 in terms of inductance, resistance and coupling coefficient and Q-factor of the transformer arrangement.

Such improvements can be attributed primarily to two factors, namely: metal leadframe portions under the transformer 18 such as the portions 1200 in FIG. 1 can be dispensed with; and/or the conventional wiring 120 is replaced with electrically conductive lines (traces) formed at the layers L0 and L1 to L4.

Modulating the thickness of the electrically conductive traces facilitates reducing the associated electrical resistance and to increase the Q-factor. Such an approach is hardly feasible in the presence a leadframe having a fixed thickness.

Advantageously, the respective patterns of electrically conductive material are grown, e.g., via plating, on the electrically insulating material of the layers L0, L1, L2, L3, L4.

A sequence which may be applied in manufacturing packages 10 as exemplified in FIGS. 3 to 8, will now be described in connection with FIGS. 9A to 9L.

It will be otherwise appreciated that the sequence of steps of FIGS. 9A to 9L is merely exemplary insofar as: one or more steps illustrated in FIGS. 9A to 9L can be omitted, performed in a different manner (with other tools, for instance) and/or replaced by other steps; additional steps may be added; and one or more steps can be carried out in a sequence different from the sequence illustrated.

FIG. 9A is exemplary of the lamination (at a “wafer” level) of a first layer L0 onto a semiconductor chip or die 14.

It is noted that solutions described herein apply to arrangements where a plural chips or dice 14 are present and to arrangements comprising a single chip or die 14.

Likewise, while arrangements including plural coils (e.g., the primary and secondary windings 181, 182 of a transformer 18) are shown in the figures, the solutions described herein apply also to arrangements where a single coil is present.

FIG. 9B is exemplary of through vias 1000 being formed (in a manner known per se to those of skill in the art, e.g., via laser beam processing) through the layer L0.

FIG. 9C is exemplary of wafer grinding and dicing (e.g., via a cutting blade) as indicated at B.

FIG. 9D is exemplary of (re)construction of a panel using a carrier 1002 onto which the structure obtained in FIG. 9C is mounted “upside down” via an intermediate layer (a tape 1004, for instance).

FIG. 9E is exemplary of encapsulation material (intended to form the support 180) being molded with subsequent mold grinding. Starting from FIG. 9E a single chip or die 14 is shown for simplicity.

FIGS. 9A to 9E are thus exemplary of a semiconductor chip 14 being embedded at a first portion of an insulating encapsulation 180 via steps including: singulating a semiconductor wafer comprising a plurality of semiconductor chips 14 into a plurality of individual semiconductor chips comprising that semiconductor chip 14; arranging the plurality of individual semiconductor chips 14 thus obtained on a temporary carrier 1002, 1004; and molding an encapsulation material onto such a plurality of (individual) semiconductor chips, thus embedding that plurality of individual semiconductor chips in an insulating encapsulation 180.

FIGS. 9A to 9E are exemplary of an advantageous arrangement wherein a base layer is formed on a surface of the semiconductor chip 14, such base layer including electrically insulating material L0 as well as a respective pattern 1000 of electrically conductive material having a desired geometrical distribution.

The step of FIG. 9E is followed in FIG. 9F by panel release and transfer of the arrangement as obtained in FIG. 9E (again turned upside down) onto a further carrier 1002′ via an associated layer (such as tape 1004′).

It is noted that, while indicated with a different reference for clarity, the carrier 1002′ and layer 1004′ may be the same type of carrier 1002 and layer 1004.

FIGS. 9G and 9H are exemplary of a sub-sequence of steps leading to the vias 1000 being made (fully) electrically conductive.

These steps may include: a “seed” layer being formed, e.g., with Ti/Cu being applied via sputtering SP into the drilled vias 1000; dry film lamination; Laser Direct Imaging (LDI) and develop; Cu galvanic growth; and Cu/Ti etching, to complete the formation of electrically conductive contacts at the vias 1000.

These steps can be carried out in a manner known per se to those of skill in the art, also as regards possible alternatives for forming the seed layer.

The foregoing is followed by lamination of a layer L1 as discussed in the foregoing.

That is, processing of the base layer L0 in the stacked structure comprises forming (e.g., via deposition—by sputtering SP, for instance, of electrically conductive material such as copper or titanium) in the electrically insulating material of the base layer L0 in the stacked structure a respective pattern of locations promoting growth of electrically conductive material.

Electrically conductive material 1000 is then grown at those locations promoting growth of electrically conductive material.

FIG. 9I is exemplary of steps as likewise discussed in the foregoing (namely dry film lamination (LDI) and develop, Cu galvanic growth, Cu/Ti etch) resulting in the formation of electrically-conductive lines and contacts (collectively indicated by 1006 for simplicity) providing, e.g., one of the coils 181, 182 of the transformer 18 and the associated wiring 120 followed by lamination of a further layer L2.

It is noted that forming a seed layer (e.g., a Ti/Cu layer as applied via sputtering SP into the drilled vias 1000) is no longer needed in the subsequent steps of FIGS. 91 onwards insofar as in these subsequent steps plating of, e.g., Cu can take place on a homologous underlying layer (e.g., electrolytically plated copper).

FIG. 9J is exemplary of steps as discussed in the foregoing (namely dry film lamination (LDI) and develop, Cu galvanic growth, Cu/Ti etch) being once more repeated leading to the formation of electrically-conductive lines and contacts (collectively indicated by 1008 for simplicity) providing, e.g., the other of the coils 181, 182 of the transformer 18 and the associated wiring 120 followed by lamination of a still further layer L3.

The same sequence of steps can be repeated as illustrated in FIG. 9K to provide additional contacts, thus providing, in the case of a final layer L4, contacts suited to act as leads 12B for the package 10.

Finally, FIG. 9L is exemplary of the release of the panel thus formed from the carrier 1002′ and subsequent finishing steps such as electroless nickel immersion gold (ENIG) finishing of the leads 12B, as indicated at P12 and singulation.

Devices as considered herein may comprise one or more electrically conductive coils, such as, for instance a first electrically conductive coil 181 having a first planar coil geometry as well as a second electrically conductive coil 182 having a second planar coil geometry that facilitates inductive coupling to the first electrically conductive coil 181 to provide a transformer circuit.

The stacked structure of layers may thus comprise a first layer (e.g., L2) of electrically insulating material having a first pattern (e.g., 1006) of electrically conductive material. That first pattern has the first planar coil geometry and provides the first electrically conductive coil e.g., 181: this can be either the primary or the secondary winding of the transformer.

The stacked structure of layers may then comprise a second layer (e.g., L3) of electrically insulating material having a second pattern (e.g., 1008) of electrically conductive material at said second layer (L3). That second pattern has the second planar coil geometry and provides the second electrically conductive coil e.g., 182: this can be either the secondary or the primary winding of the transformer.

Devices as illustrated herein (in FIGS. 3 onwards) comprise, in addition to two electrically conductive coils 181, 182, a first and a second semiconductor chip 14 arranged at the first portion of the substrate 180.

In that case the stacked structure of layers comprises: a third layer (e.g., L0) of electrically insulating material having a third pattern (e.g., 1000) of electrically conductive material providing a geometrical distribution of electrically conductive connections of the first semiconductor chip to the first electrically conductive coil 181 of the transformer circuit; and a fourth layer (e.g., L4) of electrically insulating material having a fourth pattern (e.g., 12B) of electrically conductive material providing a geometrical distribution of electrically conductive connections 120 of the second semiconductor chip 14 to the second electrically conductive coil 182 of the transformer circuit 181, 182.

Without prejudice to the underlying principles, the details and embodiments may vary, even significantly, with respect to what has been described by way of example only without departing from the extent of protection.

The extent of protection is determined by the annexed claims.

1. A method, comprising:
embedding at least one semiconductor chip in a first portion of an insulating encapsulation; and
forming at least one electrically conductive coil over a second portion of the insulating encapsulation embedding the at least one semiconductor chip, said second portion at least partly non-overlapping with the first portion of the insulating encapsulation, wherein the at least one electrically conductive coil has a planar coil geometry and a geometrical distribution of electrically conductive connections to the at least one semiconductor chip;
wherein forming comprises: forming a stacked structure of layers over the insulating encapsulation, wherein layers in the stacked structure include electrically insulating material and respective patterns of electrically conductive material;
wherein said respective patterns of electrically conductive material have:
said planar coil geometry to provide said at least one electrically conductive coil; and
said geometrical distribution to provide said electrically conductive connections.

2. The method of claim 1, wherein embedding comprises:
singulating a semiconductor wafer comprising a plurality of semiconductor chips into a plurality of individual semiconductor chips which include the at least one semiconductor chip;
arranging the plurality of individual semiconductor chips on a temporary carrier;
molding an encapsulation material onto the plurality of individual semiconductor chips to embed said plurality of individual semiconductor chips in said insulating encapsulation.

3. The method of claim 2, wherein forming the stacked structure of layers comprises forming a base layer on a surface of the at least one semiconductor chip, said base layer including electrically insulating material as well as at least one pattern of electrically conductive material having said geometrical distribution.

4. The method of claim 3, further comprising growing said respective patterns of electrically conductive material on said electrically insulating material.

5. The method of claim 4, wherein growing said respective patterns of electrically conductive material on said electrically insulating material comprises plating.

6. The method of claim 3, wherein forming the stacked structure of layers comprises:
forming in the electrically insulating material of the base layer a respective pattern of locations promoting growth of electrically conductive material, and
growing electrically conductive material at said locations promoting growth of electrically conductive material.

7. The method of claim 6, wherein forming said respective pattern of locations comprises sputtering electrically conductive material at said locations.

8. The method of claim 6, wherein forming said respective pattern of locations comprises depositing copper or titanium.

9. The method of claim 3, wherein the layers in the stacked structure of layers are Ajinomoto Build-Up Film layers.

10. The method of claim 3, wherein the base layer formed on the surface of the semiconductor chip is an Ajinomoto Build-Up Film layer.

11. A device, comprising:
at least one semiconductor chip embedded in a first portion of an insulating encapsulation; and
at least one electrically conductive coil over a second portion of the insulating encapsulation at least partly non-overlapping with the first portion of the insulating encapsulation, said at least one electrically conductive coil having a planar coil geometry and a geometrical distribution of electrically conductive connections to the at least one semiconductor chip;
a stacked structure of layers over the insulating encapsulation having the semiconductor chip embedded in the first portion thereof, wherein the layers in the stacked structure of layers include electrically insulating material as well as respective patterns of electrically conductive material;
wherein said respective patterns of electrically conductive material have:
said planar coil geometry to provide said at least one electrically conductive coil; and
said geometrical distribution to provide said electrically conductive connections.

12. The device of claim 11, wherein said stacked structure of layers comprise, on a surface of the semiconductor chip, a base layer including electrically insulating material as well as at least one respective pattern of electrically conductive material having said geometrical distribution.

13. The device of claim 12, wherein said at least one electrically conductive coil comprises:
a first electrically conductive coil having a first planar coil geometry; and
a second electrically conductive coil having a second planar coil geometry and being inductively coupled to the first electrically conductive coil to provide a transformer circuit; and
wherein the stacked structure of layers comprises:
a first layer of electrically insulating material having a first pattern of electrically conductive material at said first layer, said first pattern having said first planar coil geometry and providing the first electrically conductive coil of said transformer circuit; and
a second layer of electrically insulating material having a second pattern of electrically conductive material at said second layer, said second pattern having said second planar coil geometry and providing the second electrically conductive coil of said transformer circuit.

14. The device of claim 13, wherein said at least one semiconductor chip comprises a first semiconductor chip and a second semiconductor chip, and wherein the stacked structure of layers comprises:
a further layer of electrically insulating material having a further pattern of electrically conductive material providing a geometrical distribution of electrically conductive connections of said first semiconductor chip to at least one of said first and second electrically conductive coils of said transformer circuit.

15. The device of claim 13, wherein the layers in the stacked structure of layers comprise Ajinomoto Build-Up Film layers.

16. The device of claim 13, wherein the base layer comprises an Ajinomoto Build-Up Film layer.
